(19) United States
(12) Patent Application Publication
(10) Pub. No.: US 2021/0348765 A1
(43) Pub. Date: Nov. 11, 2021

(54) ENERGY HARVESTING BURNER FOR COOKTOP

(71) Applicant: Eric Krohn, Binghamton, NY (US)

(72) Inventor: Eric Krohn, Binghamton, NY (US)

(21) Appl. No.: 16/867,448

(22) Filed: May 5, 2020

(51) Int. Cl. F24C 3/02; F24C 3/08

(52) U.S. Cl. CPC F24C 3/027; H01L 35/28; F23D 2900/14005; F24C 3/085

(57) ABSTRACT

A gas burner appliance for recycling wasted heat from a heating process and for distributing heat evenly to a vessel or product. A housing and a plate supported by the housing are provided for directly collecting wasted heat. A burner arm is also supported by the housing and disposed above the plate for receiving and combusting premixed fuel for uniformly distributing heat to the plate. An electric motor or a Stirling engine is supported by the housing and a gearless direct drive mechanism or chain and sprocket connect the motor to the burner arm. A thermal electric generator generates electricity directly from heat of the plate and can provide at least some of the generated electricity to the motor. A cutoff mechanism is operatively connected to the motor and to the thermal electric generator for detecting when no electricity is generated and for cutting off gas flow upon sensing that condition.

### RELATED PATENT APPLICATION

The present invention is related to published U.S. patent application no. 2016/0334109 on an application filed by the present applicant, Eric Krohn, for ENERGY HARVESTING BURNER FOR COOKTOP published on Nov. 17, 2016, and hereby includes the description therein by reference.

### FIELD OF THE INVENTION

This invention relates to gas burner appliances for use in home, commercial, and laboratory heating or cooking applications and, more particularly, to an apparatus that includes a heat source (burner) that uses a gas supply and room air that converge, mix, and combust to heat either a vessel or a product (1) by using an electric motor or a Stirling engine that gearlessly direct drives or chain drives the rotating heat source, and (2) by using a safety device for cutting off gas flow when diminishing electricity is generated.

### BACKGROUND OF THE INVENTION

The present inventor realized that wasted heat (that not absorbed by the item being heated) accounts for some 78% of the heat from a flame. In other words, only 22% of the heat applied to a vessel or product on a conventional stove is actually absorbed by the cookware.

Traditional burners provide heat concentrations which are stagnant when being utilized. While traditional burners may be able to output low BTU by allowing very little flame to be used, what flame is produced will continue to heat only a concentrated area. In addition there is a limit to how low the fuel flow can be in burner ports before combustion stops; thus there is a lower limit to the amount of heat produced and this lower limit can heat a vessel excessively so that the product burns. These problems create hot spots and could lead to over consumption of fuel when attempting delicate or prolonged heating, which in turn ruins the product or heating vessel.

Stove designers in the past have attempted to rotate the burner ports utilizing outside power sources or compressed gas. These designs, however, lack energy recycling mechanisms, are not able to be retrofitted to a variety of gas sources, and generally have complicated mechanical designs that are expensive and prone to malfunction.

Recently, the trend of burners has concentrated flames towards a central point. Often the low-BTU flame is centered in the burner and heats only the center of the cooking vessel. An excess of heat applied to any one location leads to a poor distribution of heat. In all variations of flame distribution design, the heat remains in a stable position, creating hotspots on the cooking vessel or item.

These burners have represented the main style for many years. However, due to limitations inherent in their design, these burners create hotspots on pans, and provide an abundance of heat that is often wasted or burns the vessel or product being heated. This excess use of energy is a drain on fossil fuel consumption. The present invention allows the user to help prevent overconsuming fuel, thus creating less of a drain on fossil fuels.

Millions of dollars every year are spent on cookware that boasts improved ability to effectively distribute heat in order to prevent burning, scorching, and uneven cooking. As long as flames are concentrated at small areas of cookware, however, uniform heating cannot be accomplished. By rotating the heating source the burner effectively prevents uneven heating and overheating any one area on any cookware material.

### DESCRIPTION OF RELATED ART

U.S. published patent application no. 2016/0334109 on an application filed by the present applicant, Krohn, for ENERGY HARVESTING BURNER FOR COOKTOP published on Nov. 17, 2016, describes a gas burner appliance for recycling wasted heat from a heating process and for distributing heat evenly to a vessel or product. A housing is provided and a plate for collecting wasted heat is supported by the housing. A burner arm is also supported by the housing and disposed below the plate for receiving and combusting premixed fuel for uniformly distributing heat to the plate. An electric motor is supported by the housing and a drive mechanism connects the electric motor to the burner arm. A thermal electric generator generates electricity from heat of the plate and provides at least some of the generated electricity to the electric motor.

U.S. published patent application no. 2019/0186734 on an application filed by Cowan, for METHOD AND APPARATUS FOR DISTRIBUTING HEAT FROM A BURNER published on Jun. 20, 2019, describes a method and apparatus for a gas burner head with one or more rotating burners. The gas burner head may include an outer burner and an inner burner rotating about an axis. Multiple gas burner heads may be rotatably interconnected. Rotating one or more burners within one or more gas burner heads may allow a variety of burner characteristics and or patterns. One or more gas burner heads may be used in a variety of applications.

U.S. Pat. No. 6,250,210 issued to Moreth for HIGH EFFICIENCY CAROUSEL INFRARED OVEN issued on Jun. 26, 2001, describes a high efficiency carousel pizza oven that is an oven of the open cavity or open input type which permits food access and fluid communication with the atmosphere through a proximal or front opening within the oven housing. The oven employs a solid rotating thermal reservoir in the nature of a circular panel capable of storing large amounts of thermal energy per unit of mass. Rotation of the panel assures that hot spots will not develop thereby eliminating scorching of food items cooked thereon. Provided beneath the panel, in thermal communication therewith, and preferably along a radius thereof situated substantially normal to an axis of rotation of the panel, is a flame burner which furnishes greater heat to the panel as a function of increase in distance from the axis to thereby provide cooking of uniform heating to the rotating panel as a function of increase in circumference relative to distance from the axis.

U.S. Pat. No. 5,575,638 issued to Witham, et al. for STOVE BURNER SIMMER CONTROL issued on Nov. 19, 1996, describes a pulsed flame sequence burner control in response to a user's selective manipulation of an actuator through a range of response. A microcontroller-based control module switches both a burner ignitor control and an electric valve for gas supply to the burner in a predetermined time sequence depending upon the actuator position. Preferably, one or more of a plurality of burners on a single cooking top are controlled for pulsed sequence operation, and a single actuator for each channel, preferably in a form of a rotary knob, provides a simple user interface for utilizing the pulsed flame sequence, preferably in a low gas flow or simmer cooking range.

U.S. Pat. No. 6,439,881 issued to Haynes, et al. for SPIRAL-SHAPED ATMOSPHERIC GAS BURNER issued on Aug. 27, 2002, describes an atmospheric gas burner with a spiral-shaped burner body. A plurality of ports is formed in the burner body so as to be in fluid communication with the burner's internal chamber. Preferably, the burner body includes a substantially cylindrical hub section and an arm section that is joined at one end to the hub section and bends around the hub section.

U.S. Pat. No. 3,358,736 issued to Reed, et al. for ROTARY GAS BURNER ASSEMBLY issued on Dec. 19, 1967, describes a rotary burner head having discharge ports therein so that fuel issuing therefrom rotates the burner head. The burner housing is formed to present an annular ledge adjacent the arcuate path of movement of the burner head. Means are provided to deliver a small amount of fuel to the ledge where it burns stably to maintain ignition of the main portion of fuel.

U.S. Pat. No. 7,083,123 issued to Molla for INTERNAL FLAME GAS BURNER WITH HIGH COMPACTNESS issued on Aug. 1, 2006, describes an internal flame gas burner comprising a gas injector, a vacuum tube, and an annular chamber formed by a pot covered by a cap, the chamber having an internal edge perforated with flame exit ports, and the tube having a convergent section open to the ambient air at an inlet end, and a divergent section succeeding the convergent section, ending at the outlet of the tube and opening out into the chamber, the injector being relatively closer to the inlet of the tube than to the outlet.

U.S. published patent application no. 2003/0087214 on an application filed by Wilton, et al. for CONTROLLED FLAME GAS BURNER published on Jan. 9, 2001, describes multiple fingered burner including controls for continuity of gas flow and ignition throughout all of the ports peripherally positioned around the contoured wall of the burner body. A plurality of burner parts is nested together with an indexer limiting insertion to at least one predetermined alignment in order to avoid improper fit or alignment between adjacent burner parts. In addition, the peripherally positioned ports are covered by a laterally extending lip of a cap, and at least one of the parts includes recesses adjacent the laterally extending lip to provide ignitable gas flow passages along the peripheral wall of the burner that maintain continuity of ignition at adjacent burner ports.

U.S. Pat. No. 2,646,788 issued to Locke for ROTARY GAS BURNER issued on Jul. 28, 1953, describes a domestic cooking stove for cooking with gas fuel, comprising a stationary frame having a support for a cooking utensil, a stationary gas supply pipe terminating in an upwardly directed discharge end beneath the support, a rotatably mounted tube extending substantially vertically, bearings operatively interposed between the frame and the tube for supporting the tube in rotatable relation to the frame, the lower end of the tube loosely embracing the upper end of the supply pipe in spaced and non-contacting relation thereto to provide a free space for entrance of air between the supply pipe and the tube.

U.S. published patent application no. 2007/0281267 on an application filed by Li for BURNER HEAD FOR A GAS STOVE published on Dec. 6, 2007, describes a burner head for a gas stove that can provide even-burning fire flames. The burner head for a gas stove comprises a base and an annular cover, which is characterized in that small holes through inner and outer surroundings of the annular cover are disposed at a lower portion of the annular cover and gas-exiting grooves through the inner and outer surroundings of the annular cover are disposed at an upper portion of the annular cover.

U.S. Pat. No. 3,131,685 issued to Bergfield for GRILLE ROTATOR issued on May 5, 1964, describes means providing rotating movement to the conventional types of grilles ordinarily used in preparing meats for consumption as foods. The conventional types of grilles are composed of a pan-like member supported by leg members, with the pan member being adapted to contain fuel such as charcoal. The meat-receiving grille is formed of wire mesh construction and is positioned in rotatable relation with the pan by means of a center post extending downwardly through the center of the pan. A height-adjusting lever is also provided for raising and lowering the grille with relation to the pan member with the inner end of the lever being adapted to bear against the lower end of the center post. The height-adjusting lever is further provided with a ratchet or similar device for maintaining the desired height adjustment of the grille through the center post.

U.S. published patent application no. 2014/0020730 on an application applied for by Imran, for SYSTEM FOR THERMOELECTRIC ENERGY GENERATION, published on Jan. 23, 2014, describes systems and methods for generating and delivering electricity and/or hot water for combined heat and power (CHP) using one or more fuels. A control system can be configured to monitor household electrical usage and dynamically regulate the system to operate at maximum efficiency as well as sell power to an external grid. The energy generation system includes a cold water input and a hot water output to create a temperature difference or gradient, none of which are required or used in the present invention. The present invention simply does not require water to generate electricity.

### SUMMARY OF THE INVENTION

In accordance with the present invention, there is provided a gas burner appliance for recycling wasted heat from a heating process and for distributing heat evenly to a vessel or product. A housing and a plate supported by the housing are provided for directly collecting wasted heat. A burner arm is also supported by the housing and disposed above the plate for receiving and combusting premixed fuel for uniformly distributing heat to the plate. An electric motor or a Stirling engine is supported by the housing and a gearless direct drive mechanism or chain and sprocket connect the motor to the burner arm. A thermal electric generator generates electricity directly from heat of the plate and provides at least some of the generated electricity to the motor. A cutoff mechanism is operatively connected to the motor and to the thermal electric generator for detecting when no electricity is generated and for cutting off gas flow upon sensing that condition.

The burner is unique in its ability to recycle wasted heat from the heating process and to convert it into electricity. The appliance rotates the heating body horizontally to a cooking vessel, thus allowing for prolonged low-BTU output without adding excessive heat to any single location. The motion of the burner performs without adding an energy source or mechanical device, allowing the burner to be retrofitted to a variety of gas sources. The burner consists of a housing, electric motor, and a thermal energy generator that acts as an energy harvesting device. However, any materials that harvest energy to create electricity can be used. A rotating burner arm provides the outlet for combustion.

It is therefore an object of the invention to provide a mechanism to harvest energy in a heating process.

It is a further object of the present invention to provide a mechanism to rotate a heating element via energy harvesting, thus providing power to a motor.

It is a further object of the present invention to provide a mechanism to self-autonomously operate a heating appliance, the mechanism being self-contained.

It is a further object of the present invention to provide a mechanism to utilize thermal gradient in a heating process to produce electricity.

It is an additional object of the invention to provide a cutoff mechanism to detect when no electricity is generated and for cutting off gas flow when that condition is sensed.

These and other objects and advantages of the present invention are more readily apparent with reference to the following detailed description and the accompanying drawings.

### BRIEF DESCRIPTION OF THE DRAWINGS

A complete understanding of the present invention may be obtained by reference to the accompanying drawings, when considered in conjunction with the subsequent detailed description, in which:

FIG. 1 is a schematic cross sectional diagram of a burner with housing and mechanical and electrical parts in accordance with the present invention;

FIG. 2 is a schematic cross sectional diagram of a burner with housing and direct drive in accordance with one embodiment of the invention;

FIG. 3 is a perspective view of the burner with housing and direct drive shown in FIG. 2;

FIG. 4 is another perspective view of the burner with housing and direct drive motor shown in FIG. 2;

FIG. 5 is a schematic cross sectional diagram of a burner with housing, Stirling engine, and chain and sprocket drive in accordance with another embodiment of the invention.

FIG. 6 is a perspective top view of the housing shown in FIG. 5;

FIG. 7 is a perspective side view of the housing and chain and sprocket drive shown in FIG. 5;

FIG. 8 is a perspective view of the housing and a gear drive; and

FIG. 9 is a block diagram of a gas burner system including a processor for shutting off gas supply under certain conditions.

Like reference numerals refer to like parts throughout the several views of the drawings.

### DETAILED DESCRIPTION OF THE PREFERRED EMBODIMENT

Although the following detailed description contains specific details for the purposes of illustration, those of ordinary skill in the art will appreciate that variations and alterations to the following details are within the scope of the invention. Accordingly, the exemplary embodiments of the invention described below are set forth without any loss of generality to, and without imposing limitations upon, the claimed invention.

In accordance with one aspect of this invention, a gas burner appliance is provided for recycling wasted heat from a heating process and for distributing heat evenly to a vessel or product. A housing and a plate supported by the housing are provided for directly collecting wasted heat. An electric motor or a Stirling engine is supported by the housing. A cutoff mechanism is operatively connected to the motor and to the thermal electric generator for detecting when no electricity is generated and for cutting off gas flow upon sensing that condition. In accordance with another aspect of this invention a thermal energy generator (TEG) is used to harvest the heat that is not readily absorbed by the cook vessel or item. This burner is not limited to this specific form of electrical generation and may include metals/alloys or other mechanics of converting forms of energy into electricity.

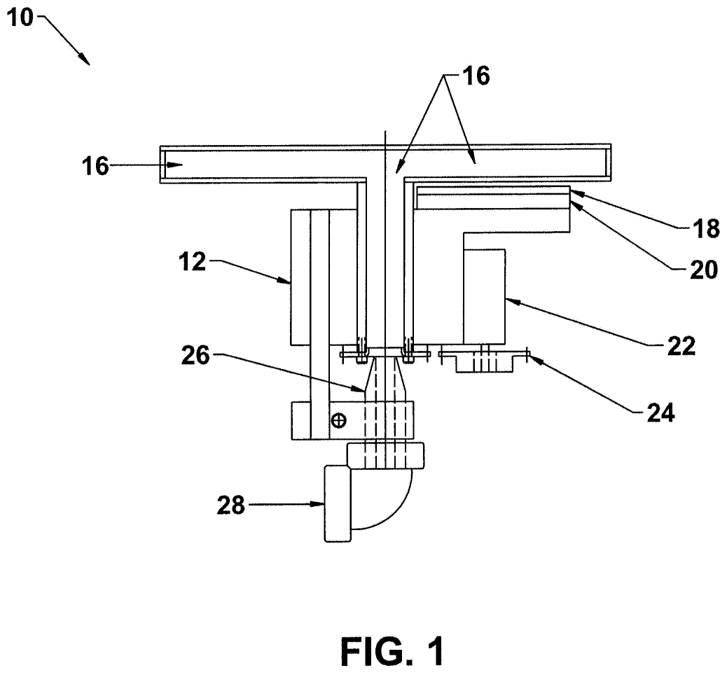

Referring now to FIG. 1, there is shown a schematic block diagram of the burner appliance, generally shown as reference numeral 10, of the present invention. A burner housing 12 attaches to a cooktop, not shown, by one of a variety of means well known to those skilled in the art. Housing 12 contains and supports the components of the burner 10, described in greater detail hereinbelow.

Disposed below rotating burner arm 16 is a plate 18 constructed of ceramic material in the preferred embodiment, although any suitable heat-conveying material can be used. Burner arm 16 can rotate while it combusts a gas and air mixture, not shown. The rotation of burner arm 16 applies substantially uniform heat directly to plate 18.

Plate 18 aids in transferring wasted heat to a thermal energy generator (TEG) 20 that produces electricity from wasted heat energy. TEG 20 utilizes heat traveling from one side of the device to a cold side in accordance with the Seebeck thermoelectric effect to create electricity. TEG 20 is shown in FIG. 1 beneath burner arm 16, but TEG 20 may be placed at any appropriate, functionally equivalent location and still be within the scope of the invention. A suitable TEG device sold under the trademark EverGen is available from II-IV Marlow Company in Dallas, Tex.

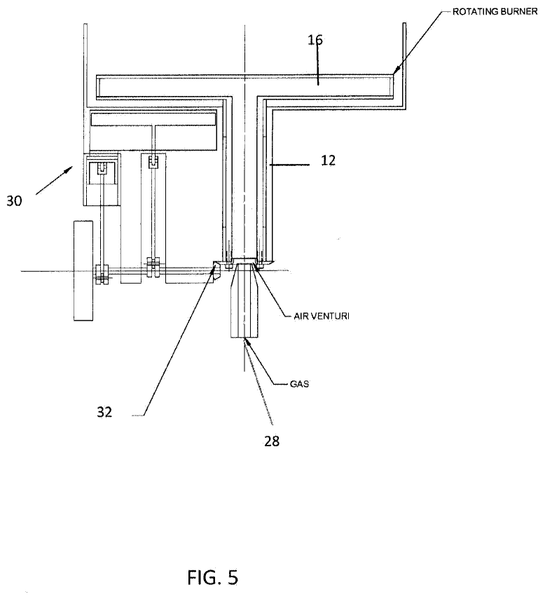

A motor 22 is also located in housing 12. In the preferred embodiment, motor 22 is preferably a 3-6-volt DC high torque motor manufactured by Tinkering Supplies Company as Model No. H04469-01J, but motor 22 need not be electric. For example, a Stirling engine, discussed in greater detail hereinbelow with reference to FIG. 5, can be used in an alternate embodiment and is still within the scope of the present invention.

Connecting motor 22 to burner arm 16 is a linkage 24, preferably a chain and sprocket manufactured by McMaster-Carr Company as Model Nos. 6789K47 and 7142k1. Alternatively, a direct drive 22 and burner arm 16 can be provided to accomplish the same task: rotating burner arm 16 above plate 18 to provide uniform heat thereto. Other linkages can be used, as are well known to those skilled in the art, but a gearless linkage is preferred, as it requires less power to activate than do gears.

Disposed beneath housing 12, as part of a stove or cooktop, is a gas/air mixing component 26 for mixing fuel and supplying the fuel to burner arm 16, which combusts the fuel for proper operation of burner 10. Supplying gas to gas/air mixing component 26 is a gas inlet 28. Gas/air mixing component 26 is preferably manufactured by CTM-Corp. for this invention.

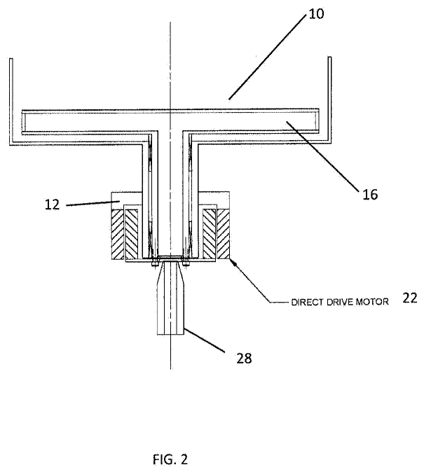

Referring now also to FIG. 2, there is shown a schematic cross sectional diagram of burner 10 with housing 12 and direct drive in accordance with one embodiment of the invention. Electric motor 22 is a 3-6-volt DC high torque motor in this embodiment, but it should be understood that another suitable electric motor can also be chosen without departing from the scope of the invention.

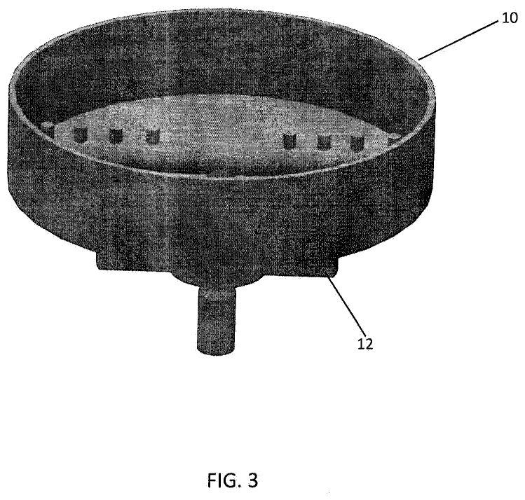

Referring now also to FIG. 3, there is shown a perspective view of burner 10 with housing 12 and direct drive shown in FIG. 2. The use of direct drive is relevant to the direct generation of electricity via the heating process and the disclosed design of burner 10. A direct relationship exists between the cooking or heating process and the direct generation of electricity which can directly be utilized by an electrical device.

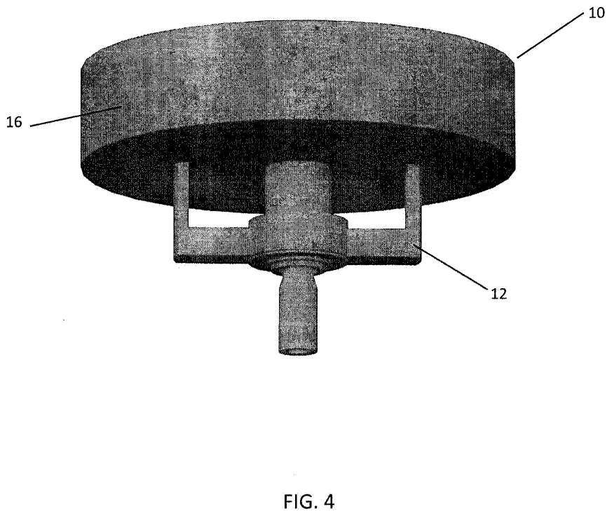

Referring now also to FIG. 4, there is shown another perspective view of burner 10 with housing 12 and direct drive motor shown in FIG. 2. The simple direct drive design of this embodiment allows for compact dimensions, the least amount of moving parts, and the most economical manufacturing, negating the need for any gears, chains, or belts.

Referring now also to FIG. 5, there is shown a schematic cross sectional diagram of burner 10 with housing 12, a Stirling engine 30, and chain and sprocket drive 32 in accordance with another embodiment of the invention. A Stirling engine is a heat engine operated by a cyclic compression and expansion of gas at different temperatures, converting heat energy to mechanical work. Stirling engine 30 runs directly on any available heat source 16 and is a viable alternative to an electric motor when a source of electricity is not available at or near the inventive energy harvesting burner apparatus 10. In the preferred embodiment, a miniature Stirling engine 30 is a Model No. DLTD-203 manufactured by the DjuiinoStar Inc.

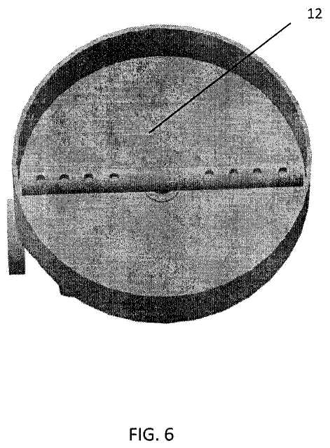

Referring now also to FIG. 6, there is shown a perspective top view of housing 12 shown in FIG. 5, demonstrating how this design allows for complete freedom of burner arm 16 to rotate without interference from other objects.

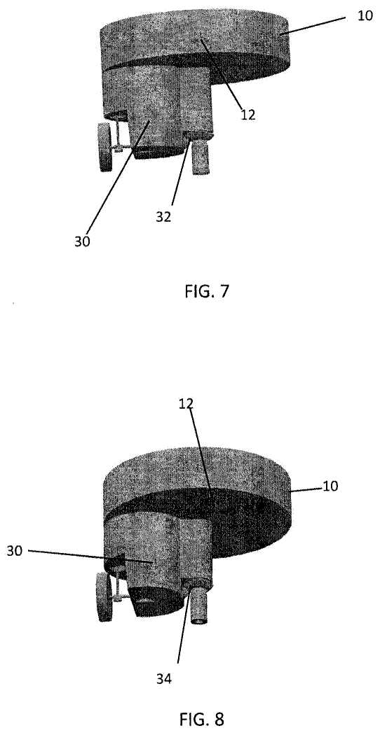

Referring now also to FIG. 7, there is shown a perspective side view of housing 12 and chain and sprocket drive 32 shown in FIG. 5. Optimally the chain and sprocket drive would be manufactured with low resistance metals that are designed for durability.

Referring now also to FIG. 8, there is shown a perspective view of housing 10 and a gear drive 34 connecting the output of Stirling engine 30 to plate 16. In the best situation, the housing 12 and gear drive 34 are manufactured with a light and durable metal for long operation.

In operation, combustible gas (not shown) is introduced into the burner gas inlet 28. As gas rises to gas/air mixing component 26, it is allowed to mix with room air (not shown). The premixed gas/air mixture enters housing 12. When gas/air mixture leaves orifices of burner arm 16, it is combusted and used for heating applications.

Due to the inefficiencies of the heating process, TEG 20 is utilized. Plate 18, secured above TEG 20, becomes hot, collecting wasted heat. Electricity generated by TEG 20 is applied to electric motor 22, which turns linkage 24 connected to rotating burner arm 16 for rotation thereof.

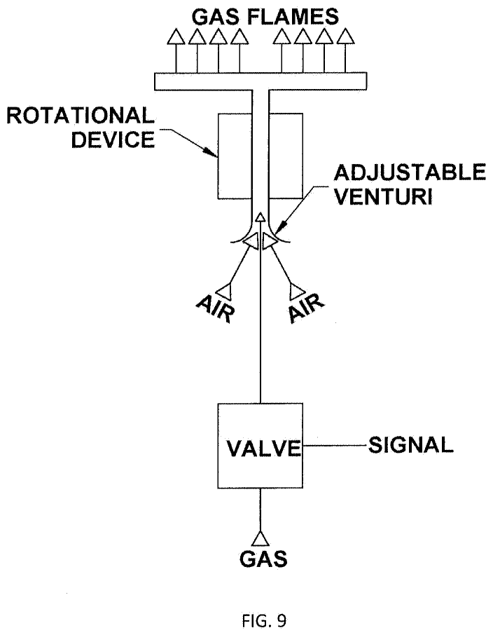

Referring now to FIG. 9, there is shown a block diagram of gas burner system 10 including a processor for shutting off gas supply under certain conditions. Specifically, burner 10 generates electricity when heat below the cooking vessel builds up enough to pass through TEG generators and thus generate current. When the cooking vessel is not on the stove, the majority of heat is lost to the environment and hence not passed through TEG generator, so a simple electronic control senses that electricity is being generated (i.e., the burner turns) and senses that electricity is not being produced. A simple 0.25 volt signal generated=on, 0.0 volt signal generated=off. When the electrical control moves from on to off, a signal is sent to gas control and triggers it to close, thus cutting off the gas supply. This is a simple and direct call and response method when processor detects a lack of electrical input and thus produces a shut off of the gas supply.

It can be appreciated that the inventive technology reduces the amount of gas used by the user, making the burner an energy saver for both home and commercial applications. Since the intent is to reduce the amount of heat delivered to the pan bottom, this rotary burner uses less gas than conventional simmer burners, resulting in cost savings and reduced use of natural resources. In addition, due to the rotating heating body, the burner provides improved evenness of cooking, saving food loss.

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application. (For example, a reference that is partially inconsistent is incorporated by reference except for the partially inconsistent portion of the reference). All patents and publications mentioned in the specification are indicative of the levels of skill of those skilled in the art to which the invention pertains. References cited herein indicate the state of the art as of their publication or filing date and it is intended that this information can be employed herein, if needed, to exclude specific embodiments that are in the prior art.

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a great number of variations of the devices, device components, and method steps set forth in the present description. As will be obvious to one of skill in the art, methods and devices useful for the present methods can include a great number of optional composition and processing elements and steps.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of,” and “consisting of” may be replaced with either of the other two terms. The invention illustratively described herein suitably may be practiced in the absence of any element or elements, limitation or limitations which is not specifically disclosed herein.

Since other modifications and changes varied to fit particular operating requirements and environments will be apparent to those skilled in the art, the invention is not considered limited to the example chosen for purposes of disclosure and covers all changes and modifications which do not constitute departures from the true spirit and scope of this invention.

While only a few exemplary embodiments have been described, those knowledgeable in this science will easily appreciate that many modifications are possible in the exemplary embodiments without materially departing from the novel and unique advantages of this disclosure. Accordingly, all such modifications and alternative are intended to be included within the scope of the invention as defined in the following claims. Those skilled in this science should recognize that such modifications and equivalent constructions or methods do not depart from the spirit and scope of the present disclosure, and that they may make various changes, substitutions, and alterations herein without departing from the spirit and scope of the present disclosure.

Having thus described the invention, what is desired to be protected by Letters Patent is presented in the subsequently appended claims.

What is claimed is:

1. A gas burner appliance for recycling wasted heat from a gas-fueled heating process and for distributing heat evenly to a vessel or product, comprising:
a) a housing;
b) a plate for directly collecting wasted heat, the plate supported by the housing;
c) a burner arm supported by the housing and disposed above the plate for receiving and combusting premixed fuel for uniformly distributing heat to the plate;
d) a motor supported by the housing;
e) drive means operatively connecting the motor to the burner arm; and
f) a thermal electric generator for generating electricity directly from heat of the plate and for providing at least some electricity to the motor for the operation thereof.

2. The gas burner appliance in accordance with claim 1, wherein the drive means comprises a chain and sprocket.

3. The gas burner appliance in accordance with claim 1, wherein the drive means is a direct drive.

4. The gas burner appliance in accordance with claim 1, wherein the motor is an electric motor.

5. The gas burner appliance in accordance with claim 1, wherein the motor is a Stirling engine.

6. The gas burner appliance in accordance with claim 1, further comprising an inlet for providing combustible gas to the gas burner appliance.

7. The gas burner appliance in accordance with claim 1, further comprising a gas/air mixing component operatively connected to the burner arm for premixing fuel prior to the combustion thereof.

8. The gas burner appliance in accordance with claim 1, wherein the gas burner appliance is disposed on a gas stove.

9. The gas burner appliance in accordance with claim 1, further comprising:
g) cutoff means operatively connected to the motor and to the thermal electric generator for detecting when no electricity is generated and for cutting off gas flow when that condition is sensed.

10. A gas burner appliance for recycling wasted heat from a gas-fueled heating process and for distributing heat evenly to a vessel or product, comprising:
a) a rotatable burner arm for receiving and combusting premixed fuel;
b) a plate disposed below the burner arm for directly collecting wasted heat;
c) a motor for rotating the rotatable burner arm; and
d) a thermal electric generator proximate the plate for generating electricity directly from heat of the plate and for providing at least some electricity to the motor for the operation thereof.

11. The gas burner appliance in accordance with claim 10, wherein the motor is an electric motor.

12. The gas burner appliance in accordance with claim 10, wherein the motor is a Stirling engine.

13. The gas burner appliance in accordance with claim 10, further comprising:
e) an inlet for providing combustible gas to the gas burner appliance.

14. The gas burner appliance in accordance with claim 10, further comprising
e) a gas/air mixing component operatively connected to the burner arm for premixing fuel prior to the combustion thereof.

14. The gas burner appliance in accordance with claim 10, wherein the gas burner appliance is disposed on a gas stove.

15. The gas burner appliance in accordance with claim 10, further comprising:
e) a chain and sprocket linkage between the electric motor and the rotatable burner arm.

16. The gas burner appliance in accordance with claim 10, further comprising:
e) an inlet for providing the combustible gas to the gas burner appliance.

17. The gas burner appliance in accordance with claim 10, wherein the gas burner appliance is disposed on a gas stove.

18. The gas burner appliance in accordance with claim 10, wherein the motor is an electric motor.

19. The gas burner appliance in accordance with claim 10, wherein the motor is a Stirling engine.

20. The gas burner appliance in accordance with claim 10, further comprising:
g) cutoff means operatively connected to the motor and to the thermal electric generator for detecting when no electricity is generated and for cutting off gas flow when that condition is sensed.
